(19) United States
(12) Patent Application Publication
(10) Pub. No.: US 2025/0241087 A1
(43) Pub. Date: Jul. 24, 2025

(54) SOLAR CELL WITH REDOX FLOW BATTERY

(71) Applicant: Infineon Technologies Austria AG, Villach (AT)

(72) Inventors: Uwe KIRCHNER, Witra (AT); Daniel MAKUS, Poing (DE)

(21) Appl. No.: 18/420,139

(22) Filed: Jan. 23, 2024

(51) Int. Cl. H01L 31/053; H01M 8/04276; H01M 8/18

(52) U.S. Cl. CPC H10F 77/90; H01M 8/04276; H01M 8/188; H01M 2250/40

(57) ABSTRACT

According to some embodiments, a power system includes a solar cell, a redox flow battery arranged in a stack with the solar cell, and a shared electrode in the stack shared by the solar cell and the redox flow battery. According to some embodiments, a method includes arranging a solar cell in a stack with a redox flow battery, and providing a shared electrode in the stack shared by the solar cell and the redox flow battery.

### TECHNICAL FIELD

The present disclosure relates to power generation and storage, and more particularly to a solar cell with a stacked redox flow battery.

### BACKGROUND

Renewable source energy generators require energy storage to realize full energy utilization.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, a power system comprises a solar cell, a redox flow battery arranged in a stack with the solar cell, and a shared electrode in the stack shared by the solar cell and the redox flow battery.

According to some embodiments, a system comprises a first power system, comprising a first solar cell, a first redox flow battery arranged in a first stack with the first solar cell, and a first electrode in the first stack and shared by the first solar cell and the first redox flow battery, and a second power system connected to the first power system and comprising a second solar cell, a second redox flow battery arranged in a second stack with the second solar cell, a second electrode in the second stack and shared by the second solar cell and the second redox flow battery, and an inverter in the second stack and connected to the second redox flow battery.

According to some embodiments, a method comprises arranging a solar cell in a stack with a redox flow battery, and providing a shared electrode in the stack shared by the solar cell and the redox flow battery.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIGS. 1-4 are simplified views of a power system, in accordance with some embodiments.

FIGS. 5A and 5B are schematic diagrams of a modular system with solar cells with integrated redox flow batteries, in accordance with some embodiments.

FIG. 6 is an illustration of an example method, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

Directional terminology, such as “top”, “bottom”, “below”, “above”, “front”, “behind”, “back”, “leading”, “trailing”, etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope defined by the claims. The following detailed description, therefore, is not to be taken in a limiting sense

The term “over” and/or “overlying” is not to be construed as meaning only “directly over” and/or “having direct contact with”. Rather, if one element is “over” and/or “overlying” another element (e.g., a region is overlying another region), a further element (e.g., a further region) may be positioned between the two elements (e.g., a further region may be positioned between a first region and a second region if the first region is “over” and/or “overlying” the second region). Further, if a first element is “over” and/or “overlying” a second element, at least some of the first element may be vertically coincident with the second element, such that a vertical line may intersect the first element and the second element.

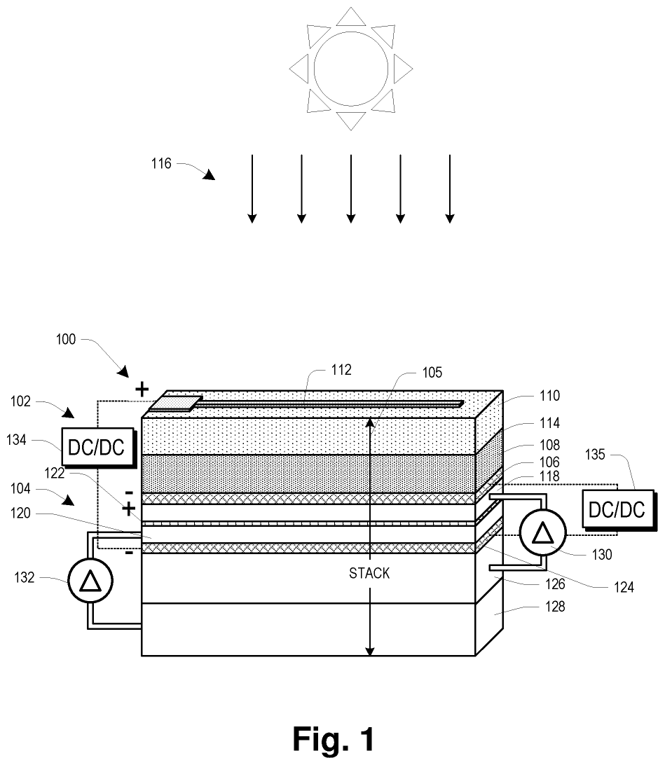

FIGS. 1-4 are simplified views of a power system 100, in accordance with some embodiments. In some embodiments, the power system 100 comprises a solar cell 102 and a redox flow battery 104 arranged in a stack 105 with a shared electrode 106. In some embodiments, the solar cell 102 is part of a larger solar module or solar panel including multiple interconnected solar cells. Multiple redox flow batteries 104 may be provided in the stack 105.

The solar cell 102 comprises a first semiconductor layer 108 over the shared electrode 106, a second semiconductor layer 110 over the first semiconductor layer 108, and a top electrode 112 over the second semiconductor layer 110. A junction 114, such as a PN junction or a heterojunction, is present at an interface between the first semiconductor layer 108 and the second semiconductor layer 110. The first semiconductor layer 108 and the second semiconductor layer 110 may comprise silicon, alloys of silicon, GaN, or some other semiconductor material. In some embodiments, a protective layer, such as a transparent conductive oxide (e.g., indium tin oxide) is provided over the second semiconductor layer 110. The top electrode 112 is sized to allow solar energy 116 to impinge on the second semiconductor layer 110 to generate electrical energy by creating a potential across the junction 114 and between the shared electrode 106 and the top electrode 112. In one example, the solar cell 102 has a size of about 100 mm-300 mm, such as 210 mm. Other structures and/or configurations of the solar cell 102 are within the scope of the present disclosure.

The redox flow battery 104 employs electrolytes, such as an anode electrolyte and a cathode electrolyte, with different oxidation states where energy is stored based on a reduction-oxidation chemical reaction. The redox flow battery 104 may use liquid anode and cathode electrolytes (liquid-liquid electrolyte redox flow battery) in a liquid phase reduction-oxidation reaction. Alternatively, the redox flow battery may use one liquid electrolyte and a solid electrolyte (liquid-solid electrolyte redox flow battery) in a liquid-solid transition, referred to as a hybrid redox flow battery. Example materials for the electrolytes include vanadium, zinc-bromine, zinc-ferricyanide, polysulfide-bromine, iron-chromium, iron-iron, organic active materials, or other suitable materials. In some embodiments, the liquid electrolytes are separated by an ion-permeable membrane. A membrane-less redox flow battery uses electrolytes, such as a metal-organic hybrid, that do not require separation.

FIG. 1 illustrates an embodiment where the redox flow battery 104 uses two liquid electrolytes, where the redox flow battery 104 comprises a first electrolyte chamber 118, a second electrolyte chamber 120, an ion permeable membrane 122 separating the first electrolyte chamber 118 and the second electrolyte chamber 120, and a bottom electrode 124. A cathode electrolyte solution may be provided in the first electrolyte chamber 118 and an anode electrolyte may be provided in the second electrolyte chamber 120. The capacity of the redox flow battery 104 depends on the amount of electrolyte material. In some embodiments, electrolyte storage tanks 126, 128 may be provided in the stack 105 and connected to the first electrolyte chamber 118 and the second electrolyte chamber 120, respectively. Circulating pumps 130, 132 may be provided to cycle the electrolyte solutions through the first electrolyte chamber 118 and the second electrolyte chamber 120. In some embodiments, the electrolyte storage tanks 126, 128 may be external to the stack 105 and connected by piping to the first electrolyte chamber 118 and the second electrolyte chamber 120.

Energy generated by the solar cell 102 charges the redox flow battery 104. In some embodiments, the solar cell 102 is connected in series with the redox flow battery 104 and a DC/DC regulator 134 charges the redox flow battery 104 using energy from the solar cell 102. In some embodiments, a DC/DC regulator 135 is connected across the redox flow battery 104 to power a load. The DC/DC regulator 135 may convert the voltage output by the redox flow battery 104 to a different voltage suitable for the load. A characteristic of the redox flow battery 104 is that the charging process is an endothermic reaction, so the redox flow battery 104 acts as a heat sink for the solar cell 102 and any other electronics in the power system 100. The efficiency of the solar cell 102 is increased by the cooling effect of charging the redox flow battery 104 during the daytime charging interval for the power system 100.

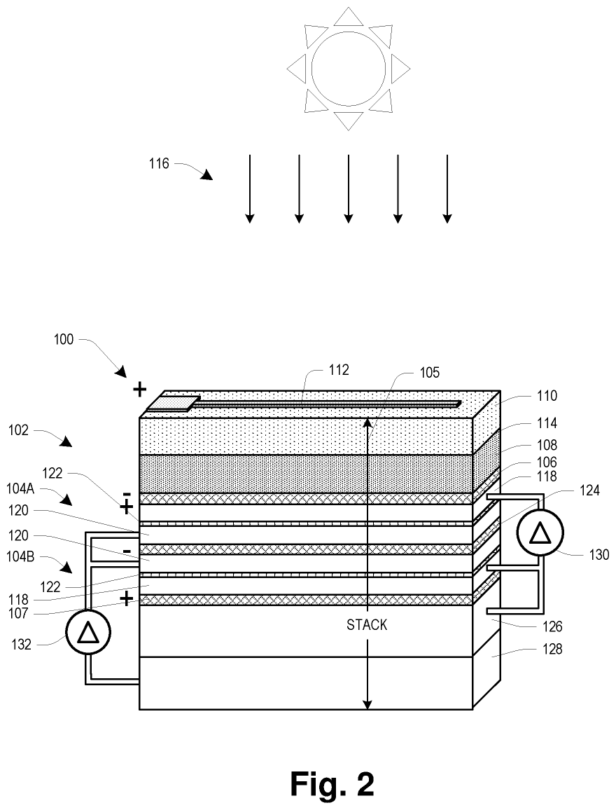

FIG. 2 illustrates an embodiment where the power system 100 comprises multiple redox flow batteries 104A, 104B in the stack 105, connected in series or in parallel depending on the desired capacity and output voltage. In some embodiments, the redox flow batteries 104A, 104B in the stack 105 have alternating polarities and thus may share electrodes, such as the bottom electrode 124. For ease of illustration, the DC/DC regulators 134, 135 are omitted in FIG. 2. The electrolyte storage tanks 126, 128 may be shared across multiple redox flow batteries 104. In one example each redox flow battery 104 may have an output from 1 V to 2V, such as 1.2V, and multiple redox flow batteries 104 may be stacked to increase the output voltage, for example to about 42V. The solar cell 102 may be part of a solar panel having dimensions of about 2 m×1 m×0.03 m that generates about 420 W of power and about 2 kWh per day. The redox flow batteries 104 may have the same size as the solar panel with a storage capacity of about 2 kWh to match the output of the solar panel.

In some embodiments, the power system 100 is assembled by bonding a first electrode of the solar cell 102 to a second electrode of the redox flow battery 104 to form the shared electrode 106. Attachment may be achieved by applying at least one of heat or pressure to a housing of the solar cell 102 to cause the materials of the first electrode of the solar cell 102 and the second electrode of the redox flow battery 104 to bond. In some embodiments, a first electrode of the solar cell 102 is mounted to a second electrode of the redox flow battery 104 by a conductive adhesive to form the shared electrode 106 having multiple layers. In some embodiments, the layers of the stack 105 are assembled as frames and the frame of the solar cell 102 including the first electrode is mounted to the frame including the first electrolyte chamber 118 so as to seal an open face of the first electrolyte chamber 118.

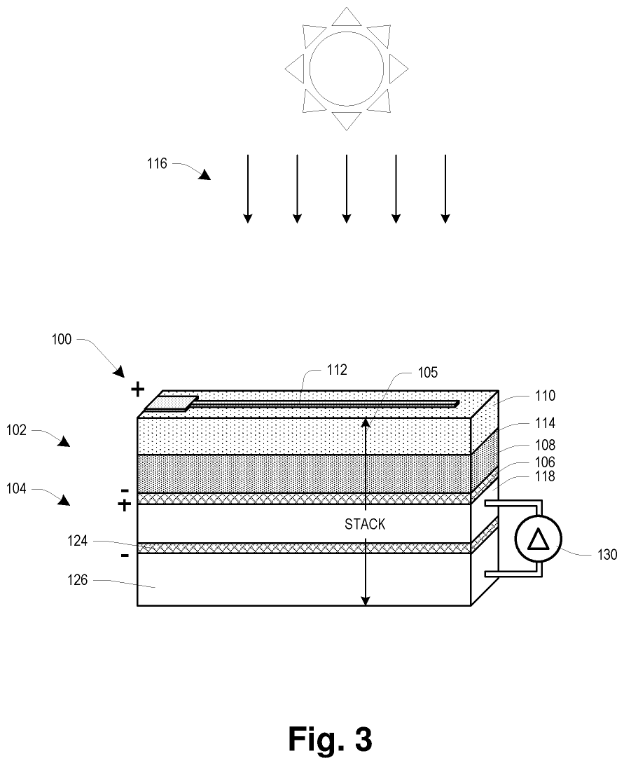

FIG. 3 illustrates an embodiment where the redox flow battery 104 is a membrane-less flow battery, in accordance with some embodiments. In a membrane-less embodiment, the ion permeable membrane 122, the second electrolyte chamber 120, and the electrolyte storage tank 128 (shown in FIG. 1) are omitted. In some embodiments, the electrolyte storage tank 126 and the circulating pump 130 are provided to increase the capacity of the redox flow battery 104. For ease of illustration, the DC/DC regulators 134, 135 are omitted in FIG. 3.

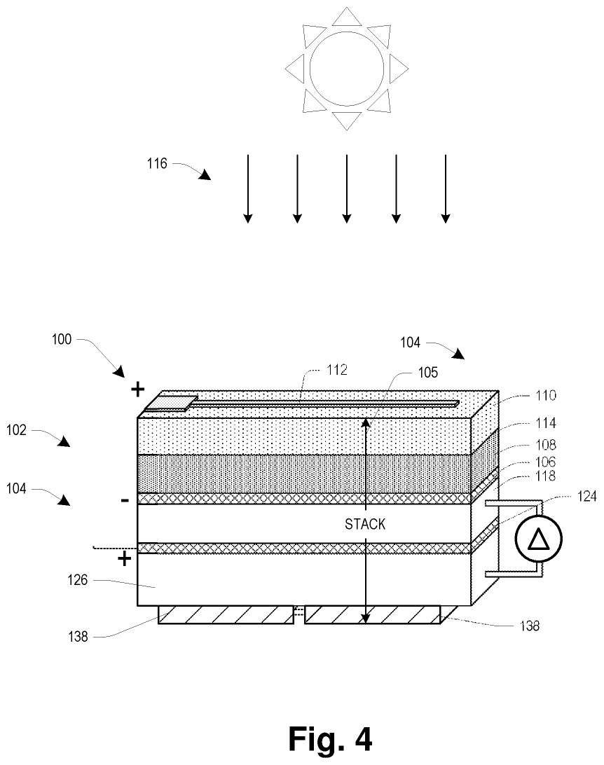

FIG. 4 illustrates an embodiment where the power apparatus comprises at least one electronic device 138 in the stack 105, in accordance with some embodiments. Although the embodiment of FIG. 4 illustrates a membrane-less redox flow battery, the electronic device 138 may be provided with the embodiments of FIG. 1, 2, or 3 or with other variations described herein. The redox flow battery 104 also acts as a heat sink for the electronic device 138. In some embodiments, the electronic device 138 may be mounted to the redox flow battery 104 using an adhesive or molding compound, such as epoxy resin. The electronic device 138 may be the DC/DC regulator 134 that charges the redox flow battery 104 using energy from the solar cell 102. In some embodiments, the electronic device 138 is an inverter that receives DC power from the redox flow battery 104 and generates AC output power to an AC load, such as a power grid. The electronic device 138 may be a voltage regulator or voltage converter that receives a first DC voltage from the power system 100 and generates a second DC voltage to power an attached device, such as the DC/DC regulator 135. The electronic device 138 may be an interface for connecting multiple power systems 100 in parallel or in series. The electronic device 138 may be connected across the solar cell 102, the redox flow battery 104, or the load by various electrical connections. Integrating the solar cell 102, the redox flow battery 104, and the electronic device 138 reduces the footprint of the power system 100.

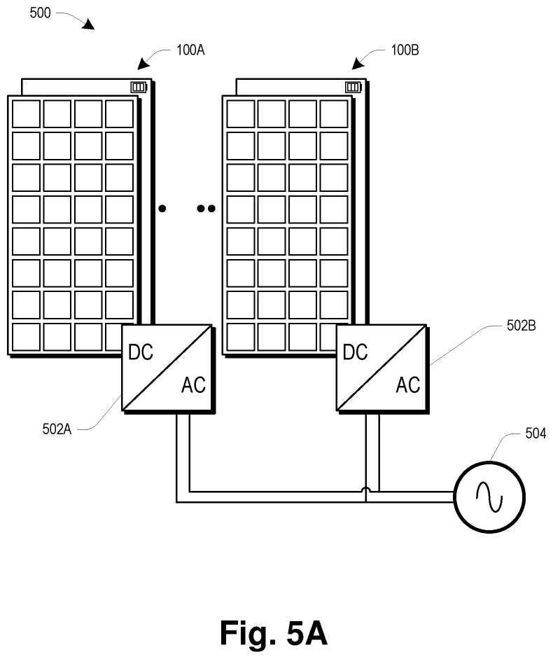

FIGS. 5A and 5B are schematic diagrams of a modular system 500 with solar cells 102 with integrated redox flow batteries 104, in accordance with some embodiments. Referring to FIG. 5A, the modular system 500 comprises a power system 100A connected to a power system 100B. Additional power systems may be connected between the power system 100A and the power system 100B. Each power system 100A, 100B may be a solar module or solar panel comprising multiple solar cells 102 and one or more redox flow batteries 104 in a stack 105 with the solar cells 102. In the embodiment of FIG. 5A, the power systems 100A, 100B comprise inverters 502A, 502B that generate AC power from the DC output of the power systems 100A, 100B to power a load 504, such as a power grid. In some embodiments, the inverters 502A, 502B are electronic devices 138 in the same stack 105 as the solar cells 102 and the redox flow battery 104. In the arrangement of FIG. 5A, outputs of the inverters 502A, 502B in the power systems 100A, 100B are connected in parallel to the load 504, where the total amount of power provided can be scaled based on the number of power systems 100A, 100B. The internal regulators for the power systems 100A, 100B, such as the DC/DC regulator 134 for charging the redox flow battery 104 using energy from the solar cell 102 are not illustrated in FIG. 5A.

Referring to FIG. 5B, the modular system 500 comprises a power system 100C connected to a power system 100D. Additional power systems 100 may be connected between the power system 100C and the power system 100D. Each power system 100C, 100D may be a solar module or solar panel comprising multiple solar cells 102 and one or more redox flow batteries 104 in a stack 105 with the solar cells 102. In the embodiment of FIG. 5B, the power systems 100C, 100D are connected by direct current (DC) devices 506A, 506B. The DC devices 506A, 506B may be simple interconnect devices to facilitate connections between the redox flow batteries 104 of the power systems 100C, 100D, or the DC devices 506A, 506B may be voltage converters or regulators to modify the DC output of the redox flow batteries 104 of the power systems 100C, 100D. The power systems 100C, 100D may be connected in series to increase the output voltage, or the power systems 100C, 100D may be connected in parallel to increase the load current. The power system 100D comprises an inverter 508 that generates AC power from the DC output of the power systems 100A, 100B to power the load 504, such as a power grid. DC power from the power systems 1000, 100D may be provided to a connector 510 to allow charging of connected devices 512, such as handheld devices, tablets, computers, or some other device. In some embodiments, at least one of the DC devices 506A, 506B or the inverter 502A, 502B is an electronic devices 138 in the stack 105 with the solar cells 102 and the redox flow battery 104. The internal regulators for the power systems 100A, 100B, such as the DC/DC regulator 134 for charging the redox flow battery 104 using energy from the solar cell 102 are not illustrated in FIG. 5B.

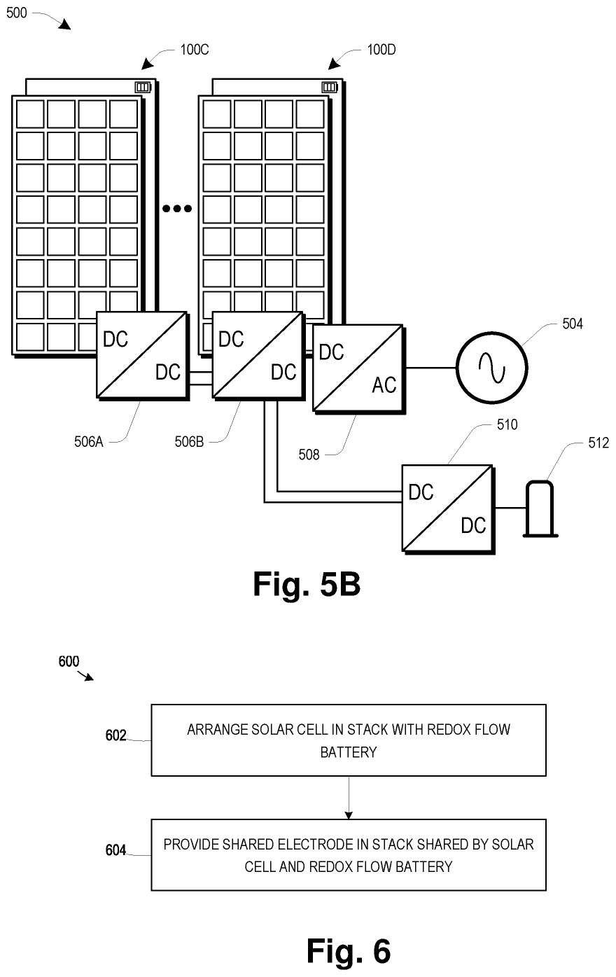

FIG. 6 is an illustration of an example method 600. At 602, a solar cell 102 is arranged in a stack 105 with a redox flow battery 104. At 604, a shared electrode 106 is provided in the stack shared by the solar cell 102 and the redox flow battery 104.

It may be appreciated that by applying one or more of the techniques described herein, such as by forming a stack 105 including a solar cell 102 and a redox flow battery 104, the footprint of the power system 100 may be reduced. Cooling provided by the charging of the redox flow battery 104 may serve to increase the efficiency of the solar cell 102. Electronic devices 138 in the stack 105 may also be cooled by the redox flow battery 104.

According to some embodiments, a power system comprises a solar cell, a redox flow battery arranged in a stack with the solar cell, and a shared electrode in the stack shared by the solar cell and the redox flow battery.

According to some embodiments, the solar cell comprises a first semiconductor layer, a second semiconductor layer over the first semiconductor layer, a top electrode over the second semiconductor layer, and a junction defined at an interface between the first semiconductor layer and the second semiconductor layer, wherein the second semiconductor layer is over the shared electrode.

According to some embodiments, the solar cell is part of a solar panel comprises multiple solar cells, and the solar panel is in the stack with the redox flow battery.

According to some embodiments, the power system comprises a second redox flow battery in the stack, wherein a second shared electrode is shared by the redox flow battery and the second redox flow battery.

According to some embodiments, the redox flow battery comprises an electrolyte chamber in the stack under the shared electrode.

According to some embodiments, the redox flow battery comprises an electrolyte storage tank connected to the electrolyte chamber, and a circulating pump to exchange fluid between the electrolyte storage tank and the electrolyte chamber.

According to some embodiments, the redox flow battery comprises a first electrolyte chamber in the stack under the shared electrode, a second electrolyte chamber in the stack, and a membrane separating the first electrolyte chamber and the second electrolyte chamber.

According to some embodiments, the redox flow battery comprises a first electrolyte storage tank in the stack and connected to the first electrolyte chamber, a first circulating pump to exchange fluid between the first electrolyte storage tank and the first electrolyte chamber, a second electrolyte storage tank in the stack and connected to the second electrolyte chamber, and a second circulating pump to exchange fluid between the second electrolyte storage tank and the second electrolyte chamber.

According to some embodiments, the power system comprises an electronic device in the stack and connected to the redox flow battery.

According to some embodiments, the redox flow battery comprises at least one of a liquid-liquid electrolyte redox flow battery, a liquid-solid electrolyte redox flow battery, or a membrane-less redox flow battery.

According to some embodiments, a system comprises a first power system, comprising a first solar cell, a first redox flow battery arranged in a first stack with the first solar cell, and a first electrode in the first stack and shared by the first solar cell and the first redox flow battery, and a second power system connected to the first power system and comprising a second solar cell, a second redox flow battery arranged in a second stack with the second solar cell, a second electrode in the second stack and shared by the second solar cell and the second redox flow battery, and an inverter in the second stack and connected to the second redox flow battery.

According to some embodiments, the first power system comprises a second inverter in the first stack and connected to the first redox flow battery, wherein an output of the inverter in the second power system is connected in parallel with an output of the second inverter in the first power system.

According to some embodiments, the first power system comprises a first direct current device in the first stack and connected to the first redox flow battery, the second power system comprises a second direct current device in the second stack and connected to the second redox flow battery, the first direct current device is connected to the second direct current device, and the second direct current device is connected to the inverter in the second power system.

According to some embodiments, at least one of the first redox flow battery or the second redox flow battery comprises at least one of a liquid-liquid electrolyte redox flow battery, a liquid-solid electrolyte redox flow battery, or a membrane-less redox flow battery.

According to some embodiments, a method comprises arranging a solar cell in a stack with a redox flow battery, and providing a shared electrode in the stack shared by the solar cell and the redox flow battery.

According to some embodiments, providing the shared electrode comprises bonding a first electrode of the solar cell with a second electrode of the redox flow battery to form the shared electrode.

According to some embodiments, providing the shared electrode comprises mounting a first electrode of the solar cell with a second electrode of the redox flow battery with a conductive adhesive to form the shared electrode.

According to some embodiments, the method comprises arranging a second redox flow battery in the stack and connected to the redox flow battery, and providing a second shared electrode in the stack shared by the redox flow battery and the second redox flow battery.

According to some embodiments, the redox flow battery comprises an electrolyte chamber in the stack and the method comprises providing an electrolyte storage tank in the stack connected to the electrolyte chamber and connecting a circulating pump to the electrolyte storage tank and the electrolyte chamber.

According to some embodiments, the method comprises connecting an electronic device in the stack to the redox flow battery to generate an output voltage.

It may be appreciated that combinations of one or more embodiments described herein, including combinations of embodiments described with respect to different figures, are contemplated herein.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Moreover, “exemplary” and/or the like is used herein to mean serving as an example, instance, illustration, etc., and not necessarily as advantageous. Rather, use of the word “example” and/or the like is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

While the subject matter has been described with reference to illustrative embodiments, this description is not intended to be construed in a limiting sense. Various modifications and combinations of the illustrative embodiments, as well as other embodiments of the present disclosure, will be apparent to persons skilled in the art upon reference to the description. It is therefore intended that the appended claims encompass any such modifications or embodiments.

What is claimed is:

1. A power system, comprising:
a solar cell;
a redox flow battery arranged in a stack with the solar cell; and
a shared electrode in the stack shared by the solar cell and the redox flow battery.

2. The power system of claim 1, wherein the solar cell comprises:
a first semiconductor layer;
a second semiconductor layer over the first semiconductor layer;
a top electrode over the second semiconductor layer; and
a junction defined at an interface between the first semiconductor layer and the second semiconductor layer, wherein:
the second semiconductor layer is over the shared electrode.

3. The power system of claim 1, wherein:
the solar cell is part of a solar panel comprising multiple solar cells; and
the solar panel is in the stack with the redox flow battery.

4. The power system of claim 1, comprising:
a second redox flow battery in the stack, wherein:
a second shared electrode is shared by the redox flow battery and the second redox flow battery.

5. The power system of claim 1, wherein the redox flow battery comprises:
an electrolyte chamber in the stack under the shared electrode.

6. The power system of claim 5, wherein the redox flow battery comprises:
an electrolyte storage tank connected to the electrolyte chamber; and
a circulating pump to exchange fluid between the electrolyte storage tank and the electrolyte chamber.

7. The power system of claim 1, wherein the redox flow battery comprises:
a first electrolyte chamber in the stack under the shared electrode;
a second electrolyte chamber in the stack; and
a membrane separating the first electrolyte chamber and the second electrolyte chamber.

8. The power system of claim 7, wherein the redox flow battery comprises:
a first electrolyte storage tank in the stack and connected to the first electrolyte chamber;
a first circulating pump to exchange fluid between the first electrolyte storage tank and the first electrolyte chamber;
a second electrolyte storage tank in the stack and connected to the second electrolyte chamber; and
a second circulating pump to exchange fluid between the second electrolyte storage tank and the second electrolyte chamber.

9. The power system of claim 1, comprising:
an electronic device in the stack and connected to the redox flow battery.

10. The power system of claim 1, wherein:
the redox flow battery comprises at least one of a liquid-liquid electrolyte redox flow battery, a liquid-solid electrolyte redox flow battery, or a membrane-less redox flow battery.

11. A system, comprising:
a first power system, comprising:
a first solar cell;
a first redox flow battery arranged in a first stack with the first solar cell; and
a first electrode in the first stack and shared by the first solar cell and the first redox flow battery; and
a second power system connected to the first power system and comprising:
a second solar cell;
a second redox flow battery arranged in a second stack with the second solar cell;
a second electrode in the second stack and shared by the second solar cell and the second redox flow battery; and
an inverter in the second stack and connected to the second redox flow battery.

12. The system of claim 11, wherein the first power system comprises:
a second inverter in the first stack and connected to the first redox flow battery, wherein an output of the inverter in the second power system is connected in parallel with an output of the second inverter in the first power system.

13. The system of claim 11, wherein:
the first power system comprises a first direct current device in the first stack and connected to the first redox flow battery;
the second power system comprises a second direct current device in the second stack and connected to the second redox flow battery;
the first direct current device is connected to the second direct current device; and
the second direct current device is connected to the inverter in the second power system.

14. The power system of claim 11, wherein:
at least one of the first redox flow battery or the second redox flow battery comprises at least one of a liquid-liquid electrolyte redox flow battery, a liquid-solid electrolyte redox flow battery, or a membrane-less redox flow battery.

15. A method comprising:
arranging a solar cell in a stack with a redox flow battery; and
providing a shared electrode in the stack shared by the solar cell and the redox flow battery.

16. The method of claim 15, wherein providing the shared electrode comprises:
bonding a first electrode of the solar cell with a second electrode of the redox flow battery to form the shared electrode.

17. The method of claim 15, wherein providing the shared electrode comprises:
mounting a first electrode of the solar cell with a second electrode of the redox flow battery with a conductive adhesive to form the shared electrode.

18. The method of claim 15, comprising:
arranging a second redox flow battery in the stack and connected to the redox flow battery; and
providing a second shared electrode in the stack shared by the redox flow battery and the second redox flow battery.

19. The method of claim 15, wherein:
the redox flow battery comprises an electrolyte chamber in the stack and,
the method comprises:
providing an electrolyte storage tank in the stack connected to the electrolyte chamber; and
connecting a circulating pump to the electrolyte storage tank and the electrolyte chamber.

20. The method of claim 15, comprising:
connecting an electronic device in the stack to the redox flow battery to generate an output voltage.
